(19) United States
(12) Patent Application Publication
(10) Pub. No.: US 2007/0048984 A1
(43) Pub. Date: Mar. 1, 2007

(54) Metal work function adjustment by ion implantation

(76) Inventors: Steven Walther, Andover, MA (US); Ukyo Jeong, Andover, MA (US); Sandeep Mehta, Boxford, MA (US); Naushad Variam, Marblehead, MA (US)

Correspondence Address: HOFFMAN, WARNICK & D'ALESSANDRO LLC, 75 STATE STREET, 14TH FLOOR, ALBANY, NY, 12207, US

(21) Appl. No.: 11/217,699

(22) Filed: Aug. 31, 2005

(51) Int. Cl. H01L 21/425

(52) U.S. Cl. 438/533

(57) ABSTRACT

A system, method and program product for adjusting metal work function by ion implantation is disclosed. The invention determines the work function of the metal and determines a desired work function threshold for the metal. The desired work function threshold may be a range and is usually based on the work function of the substrate. An ion implanter system is then used to implant ions to at least a portion of the metal. The ion implantation is usually a high-energy ion stream including a material that is calculated to modify the work function of the metal. The ion implanter system continues to transmit the ion stream into the metal until the work function of the metal meets the desired work function threshold.

### BACKGROUND OF THE INVENTION

1. Technical Field

The present invention relates generally to ion implantation, and more particularly, to an ion implantation system, method and program product for adjusting metal work function.

2. Related Art

In the semiconductor industry, metal to semiconductor junctions are of great importance because they are present in every semiconductor device. A normal semiconductor device has a metal gate connected to a semiconductor substrate by a dielectric, usually an oxide layer. The work function match between gate and substrate is critical in regulating the energy band that makes a semiconductor device function correctly. A less than optimal match of the work function may cause the semiconductor device to require excessively low or high voltage to be turned on or off.

One important factor in determining whether the metal to semiconductor junction will work correctly is the work function of the materials used in fabricating the semiconductor. The “work function” of a material is a measurement of how much energy is required to extract an electron from the material by moving the electron in the solid atom from the Fermi level to the vacuum level, i.e., to outside of the atom. This energy is between three and five Volts for most metals.

If the metal gate and the semiconductor substrate are composed of different materials, there will often be what is called a work function difference between the two. FIG. 1 shows a table of work functions (wƒg) of common metals (horizontally) used in the manufacture of semiconductor devices and the work function difference of these metals with common semiconductors used as substrates (vertically). A work function difference means that one of the materials has a different affinity for electron movement than the other. This difference in affinity will cause a natural electric field to form in the semiconductor device as carriers in one material tend to migrate toward the other while a space charge region will be formed in the semiconductor where the carriers are depleted. This space charge may form an electric field. This electric field may drain energy or may require extra energy to overcome the electric field in order for the semiconductor device to function correctly. Thus, it is desirable that the gate and substrate have substantially similar work functions.

One problem in the industry is finding a metal gate material that has little or no work function difference with known substrate materials and that is also a good electrical conductor. Additionally, a material that has a resistance to temperature fluctuations is preferred. Semiconductor fabricators often use a silicon semiconductor substrate in conjunction with a polycrystalline silicon (poly-Si) gate because of the desirability to provide similar work functions. Because the gate and substrate are composed of the same substance, namely silicon, both have the same intrinsic work function. Although poly-Si normally behaves as a semiconductor it can be made to act as a conductor through a process known as doping, in which atoms of an element that readily either accept or release an electron is introduced into the poly-Si crystal matrix. This may be accomplished by in situ doping, in which the atoms are introduced during the growth of the crystal, or, more often, may be introduced after crystal formation in a process known as ion implantation. In this process, ions of the desired dopant are implanted into the surface of the target substance, in this case the poly-Si gate. As a result of the doping, the gate conducts electricity while retaining the same work function as the silicon semiconductor substrate.

However, in spite of its similarity of work function with silicon substrates, poly-Si has distinct disadvantages as a gate material. First, even though doping can enable poly-Si to conduct electricity, poly-Si still has twice the electric resistance of typical metals such as copper, aluminum, silver, gold, and titanium or compounds containing these metals. Moreover, poly-Si is easily oxidized at the interface with the gate insulator (e.g., silicon dioxide), further increasing the electric resistance.

In view of the foregoing, other typical metals are being considered as gates in semiconductor devices, which presents a challenge relative to the work function differences between the metals and silicon. Most, such as copper, silver, gold and titanium or compounds of these metals, are usually not used because of the work function difference between silicon and these metals. Aluminum has a work function that is very close to that of silicon. However, aluminum is relatively susceptible to changes in temperature. Additionally, refractory metals (R-metals) such as rhenium, niobium, tungsten, tantalum and molybdenum or compounds containing refractory metals, which would work well as gate metals because they have a high resistance to temperature, are almost never used because of the large work function difference between silicon and these metals.

In view of the foregoing, there is a need in the art for changing the work function of a metal to make it relatively equivalent to that of the semiconductor substrate.

### SUMMARY OF THE INVENTION

A system, method and program product for adjusting metal work function by ion implantation is disclosed. The invention determines the work function of the metal and determines a desired work function threshold for the metal. The desired work function threshold may be a range and is usually based on the work function of the substrate. An ion implanter system is then used to implant ions to at least a portion of the metal. The ion implantation usually includes a high-energy ion stream including a material that is calculated to modify the work function of the metal. The ion implanter system continues to transmit the ion stream into the metal until the work function of the metal meets the desired work function threshold.

A first aspect of the invention is directed to a method of adjusting a work function of a metal in a target, the method comprising the steps of: determining the work function of the metal; determining a desired work function threshold; and implanting at least a portion of the metal with ions until the work function of the metal meets the desired work function threshold.

A second aspect of the invention is directed to a system for adjusting a work function of a metal in a target, the system comprising: means for determining the work function of the metal; means for determining a desired work function threshold; and means for implanting at least a portion of the metal with ions until the work function of the metal meets the desired work function threshold.

A third aspect of the invention is directed to a computer program product comprising a computer useable medium having computer readable program code embodied therein for controlling an ion implanter system that generates ions used in adjusting a work function of a metal in a target, the program product comprising: program code configured to determine the work function of the metal; program code configured to determine a desired work function threshold; and program code configured to control the ion implanter system to implant ions into the metal until the work function meets the desired work function threshold.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows a table of work functions of common metals used in the manufacture of semiconductor devices and the work function difference with the work functions of common semiconductors used as substrates.

FIG. 2 shows a conventional ion acceleration type ion implanter system.

FIG. 3 shows a conventional plasma immersion type ion implanter system.

FIG. 4 shows a conventional semiconductor device with the metal gate being implanted with ions.

FIG. 5 shows a block diagram of a system controller of FIGS. 2-3.

FIG. 6 shows a flow diagram of operation of the metal work function adjustment system.

### DETAILED DESCRIPTION OF THE INVENTION

Ion Acceleration Type Ion Implanter System Overview

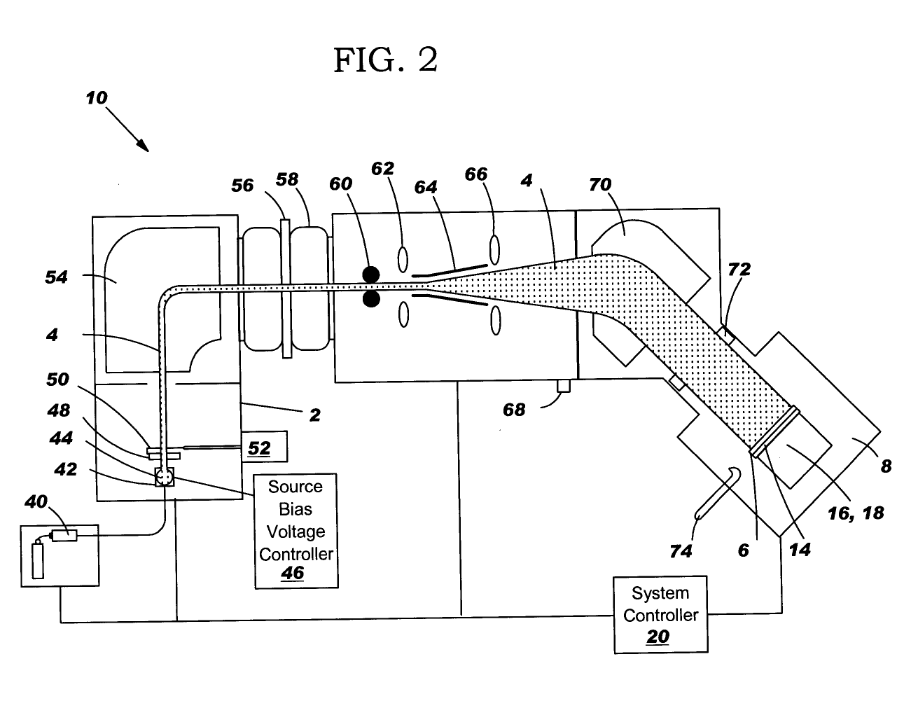

With reference to the accompanying drawings, FIG. 2 illustrates an ion acceleration type ion implanter system 10, which may be used in the present invention. Implanter system 10 includes an ion beam generator 2 for generating and transmitting an ion beam 4 to a target 6 in an implant chamber 8. Ion beam generator 2 may be any now known or later developed ion beam generator such as those available from Varian Semiconductor Equipment Associates of Gloucester, Mass. Typically, target 6 includes one or more semiconductor wafers mounted to a platen 14. Characteristics of platen 14 and, hence, target 6, may be controlled by a platen drive assembly 16 that rotates the target 6, i.e., wafer, and a target vertical scan system position controller 18 that controls the vertical position of target 6. Drive assembly 16 and position controller 18 are both responsive to a system controller 20.

Besides the above-described components, ion beam generator 2 may include a gas flow 40; an ion source 42 including a source magnet 44 and a source bias voltage controller 46; a suppression electrode 48, an extraction electrode 50 and one or more manipulator motors 52 for electrodes 48, 50; an analyzer magnet 54; an accelerator focus electrode 56; an accelerator suppression electrode 58; a mass slit 60; a pre-scan suppression electrode 62; horizontal scan plates 64; a post-scan suppression electrode 66; a nitrogen (N₂) bleed 68; a corrector magnet 70; a limiting aperture 72; and a profiler system 74. Although not shown for clarity sake, each of the above-described components is monitored by and responsive to system controller 20.

Although a sample ion acceleration type ion implanter system has been illustrated, it should be recognized that any ion acceleration type ion implanter system may be used.

Plasma Immersion Type Ion Implanter System Overview

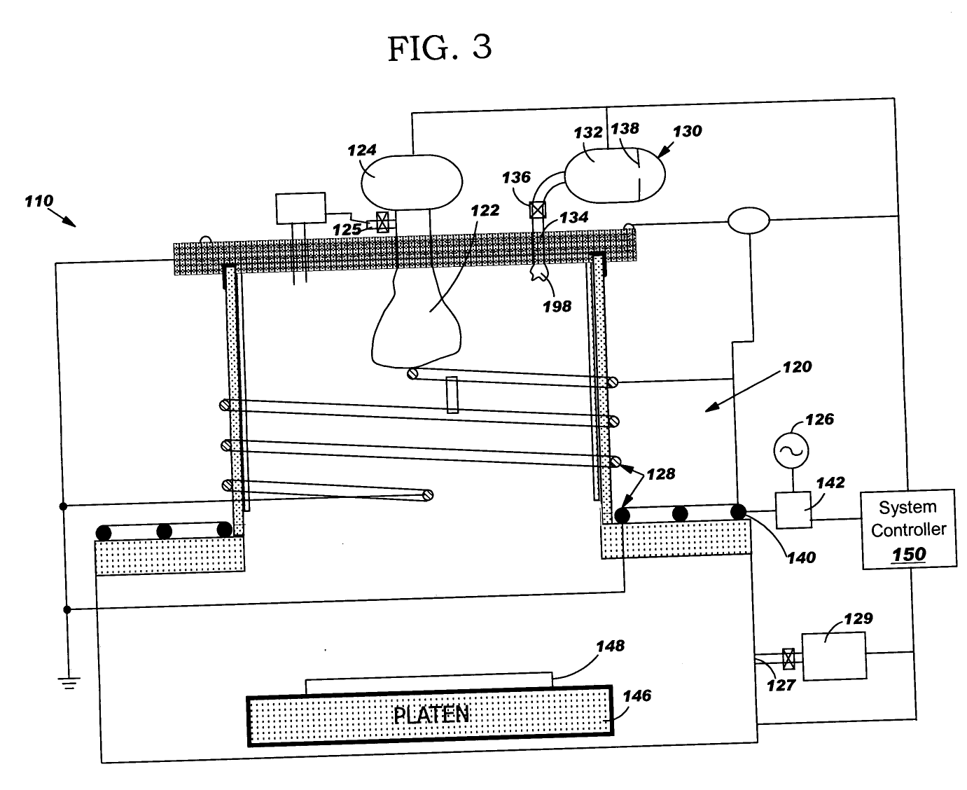

Referring to the attached drawings, FIG. 3 shows a plasma immersion type ion implanter system 110, which may be used in the present invention. Implanter system 110 includes a plasma chamber 120 configured to receive a process gas 122 from a gas source 124. A gas pressure controller 125 may be provided by, for example, a combination of upstream controller and variable position throttle valve (not shown). An exhaust port 127 is coupled to one or more vacuum pump(s) 129. Pressure controller 125 operates to maintain plasma chamber 120 pressure to a set value by fixing an inlet or exhaust conductance and varying process gas 122 flow rate in a feedback loop to allow for changing gas demand.

Implanter system 110 also includes a platen 146 for holding a target 148, e.g., a semiconductor wafer, to be implanted. In one embodiment, a radio frequency (RF) source 126 is configured to resonate radio frequency currents in a radio frequency antenna 128. RF source 126 is coupled, via an impedance match 142, to an active antenna 140 that surrounds plasma chamber 120. In the alternative, a glow discharge based plasma implant (not shown) may be used. Glow discharge based plasma implant initiates plasma by applying a bias pulse to target 148. Implanter system 110 may also have a plasma igniter 130, including a reservoir 132 of easily ionized strike gas 198 coupled to a secondary gas inlet 134 and having a shutoff “burst” valve 136. Plasma igniter 130 may optionally be intentionally separated by a conventional limited conductance 138, e.g., an orifice or metering valve, to provide a steady flow rate of strike gas 198.

Although a sample plasma immersion type ion implanter system has been illustrated, it should be recognized that any plasma immersion type ion implanter system may be used.

Metal Work Function Adjustment

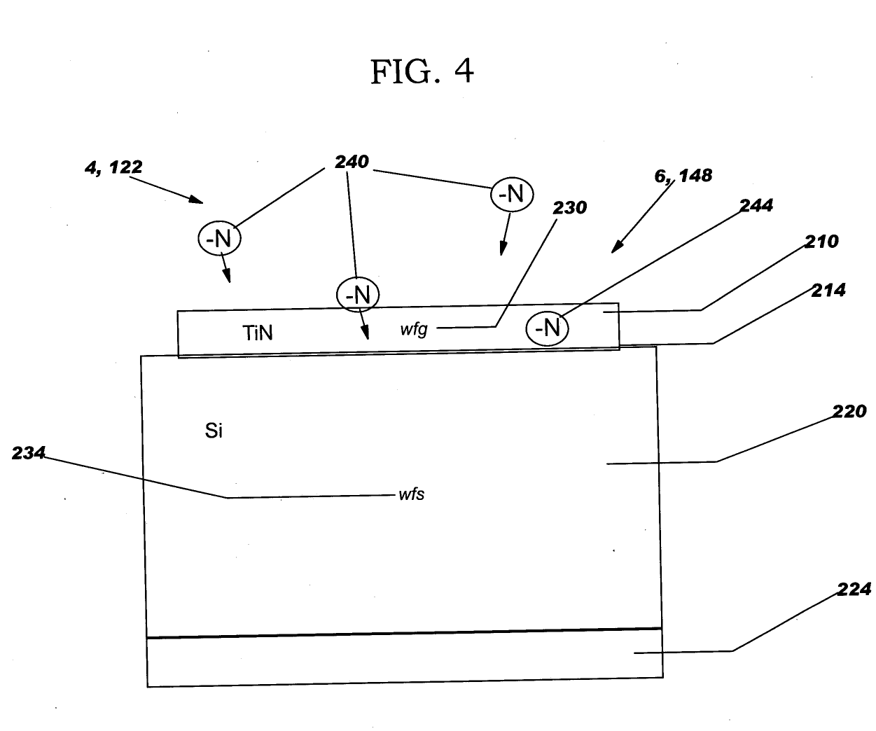

FIG. 4 shows a close-up view of one representation of target 6, 148. The invention will be described relative to a semiconductor wafer having a metal gate 20. It should be recognized, however, that the teachings of the invention are applicable to any metal. In this embodiment, target 6, 148 has a metal gate 210 and a semiconductor substrate 220 separated by a thin resistor 214. Target 6, 148 may also have a metal contact 224 coupled to substrate 220 opposite gate 210. In one embodiment, substrate 220 includes silicon, but substrate 220 may also include of germanium, gallium arsenide or any semiconductor material now known or later developed in the art. Furthermore, although gate 210 is displayed as including titanium nitride in FIG. 4, gate 210 may also include any conducting metal now known or later developed in the art, including, but not limited to common metals used as gates such as gold, silver, aluminum, copper, chromium, nickel, carbon, germanium, cobalt, silicon and platinum or compounds thereof or of refractory metals such as rhenium, niobium, tungsten, tantalum and molybdenum or compounds thereof.

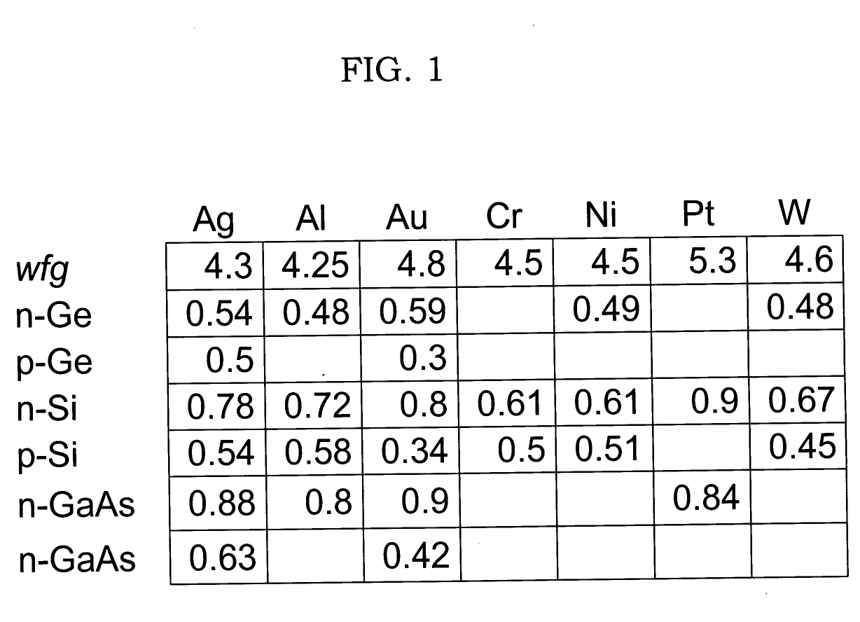

Gate 210 has a gate work function (wƒg) 230. Substrate 220 also has a substrate work function (wƒs) 234. FIG. 1 shows a table of work functions of common metals used in the manufacture of semiconductor devices and the work function difference with the work functions of common semiconductors used as substrates. The determination of these work functions is a process that is well known in the art and accordingly will not be described in detail here. The present invention alters gate work function (wƒg) 230 by causing at least one ion 240, 244 generated by an ion implanter system, such as ion acceleration type ion implanter system 10 (FIG. 2) or plasma immersion type ion implanter system 110 (FIG. 3), to be transmitted to target 6, 148 in implant chamber 8 (FIG. 2) or plasma chamber 120 (FIG. 3). Ion 240, 244 is illustrated in FIG. 4 as comprising positively charged nitrogen atoms, but ion 240, 244 may also be comprised, in this example, of positively charged titanium atoms or other positively or negatively charged atoms, which are now known or later discovered to change the work function of a metal gate of the type described herein. In this way, gate work function (wƒg) 230 may be altered to meet a desired work function threshold that is preferably substantially equivalent to substrate work function (wƒs).

System Controller Overview:

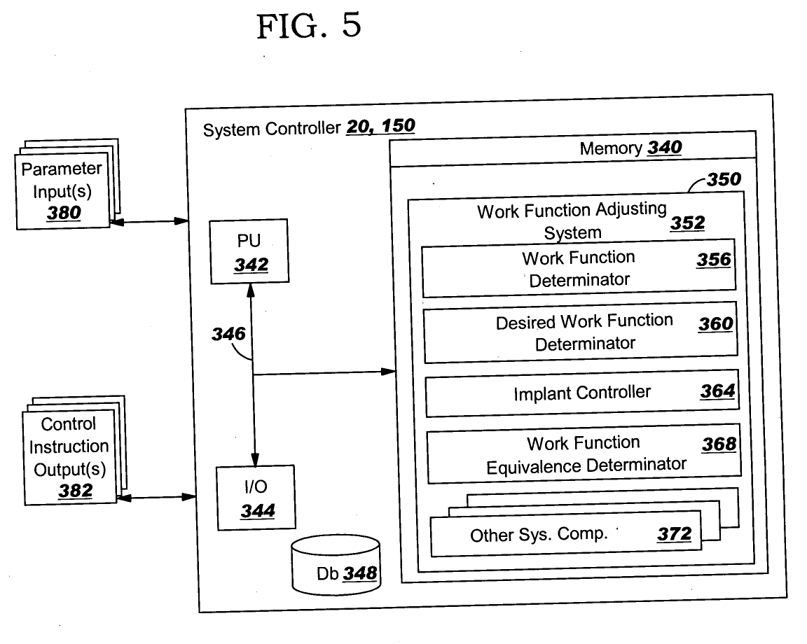

Referring to FIG. 5, a block diagram of an illustrative system controller 20, 150 is shown. System controller 20, 150 includes a computer control system responsive to ion implanter system 10, 110 (FIGS. 2-3) inputs, which would vary depending on the type of ion implanter. In one embodiment, system controller 20, 150 includes a memory 340, a processing unit (PU) 342, input/output devices (I/O) 344 and a bus 346. A database 348 may also be provided for storage of data relative to processing tasks. Memory 340 includes a program product 350 that, when executed by PU 342, comprises various functional capabilities described in further detail below. Memory 340 (and database 348) may comprise any known type of data storage system and/or transmission media, including magnetic media, optical media, random access memory (RAM), read only memory (ROM), a data object, etc. Moreover, memory 340 (and database 348) may reside at a single physical location comprising one or more types of data storage, or be distributed across a plurality of physical systems. PU 342 may likewise comprise a single processing unit, or a plurality of processing units distributed across one or more locations. I/O 344 may comprise any known type of input/output device including a network system, modem, keyboard, mouse, scanner, voice recognition system, CRT, printer, disc drives, etc. Additional components, such as cache memory, communication systems, system software, etc., may also be incorporated into system controller 20, 150.

As shown in FIG. 5, program product 350 may include a work function adjusting system 352 including a work function determinator 356, a desired work function threshold determinator 360, an implant controller 364, a work function equivalence determinator 368 and other system components 372. Other system components 372 may include any now known or later developed parts of system controller functions not individually delineated herein.

Referring to FIGS. 2, 3 and 4, inputs to system controller 20, 150 include a wide variety of ion implanter system 10, 110, user entered or other parameter inputs 380. Parameter inputs 380 may indicate particular states of ion implanter system 10, 110 and/or particular components thereof or may indicate user defined input parameters. That is, a parameter input 380 may be any characteristic of ion implanter system 10, 110, user defined constants or other variables that may affect operation of the system including, in particular to the present invention, an adjustment of gate work function (wƒg) 230 (FIG. 4). Based on the above-described components of systems such as ion implanter system 10, 110 used to adjust gate work function (wƒg) 230, parameter inputs 380 may include, for example, initial gate work function (wƒg) 230, substrate work function (wƒs) 234, desired gate work function (wƒg), rate of ion implantation and duration of ion implantation. For example, parameter input 380 may be a desired dose and energy for achieving desired gate work function (wƒg) that is determined by establishing a correlation between an implant dose and energy to initial gate work function (wƒg) 230 in a separate test. It should be recognized that the above-described list is meant to be illustrative only. For example, it is common for a conventional system controller 20, 150 to receive more than 5000 parameter inputs depending on the makeup of the ion implanter system used.

Work Function Adjusting System

Work function adjusting system 352 functions generally to control implantation of ions 240, 244 (FIG. 4) into gate 210 (FIG. 4) to adjust gate work function (wƒg) 230 (FIG. 4) (i.e., the above listed parameter inputs by controlling the above-described components) during different stages of operation. Some or all of the functions performed by components of work function adjusting system 352 may be performed outside of the particular machine used to implant ions 240, 244 (FIG. 4). Work function determinator 356 determines gate work function (wƒg) 230 (FIG. 4) of gate 210 (FIG. 4) prior to implantation of ions 240, 244 (FIG. 4). Work function determinator 356 may also continue to monitor changes in gate work function (wƒg) 230 (FIG. 4) during ion 240, 244 (FIG. 4) implantation. Desired work function threshold determinator 360 determines the desired work function threshold to which gate work function (wƒg) 230 (FIG. 4) is to be adjusted. Implant controller 364 controls implantation of ions 240, 244 (FIG. 4) by ion implanter system 10, 110 (FIGS. 2-3) into gate 210 (FIG. 4) by using a determined desired dose and energy. Dose and energy may be predetermined such as by empirical data gathered from prior implantation of the same material. In the alternative, dose and energy may be calculated using a linear approximation equation, such as work function (dose)=work function (dose=0)+X*dose, where X is an empirically determined scalar (positive or negative) that depends upon implant species, energy, target metal type and thickness, and thermal processing. The desired work function is determined to be that which will provide the same threshold voltage (to turn the transistor ‘on’) for both NMOS and PMOS transistors in the most common case. It should be understood, however, that the same threshold voltage condition requires different work functions for NMOS and PMOS.

Work function equivalence determinator 368 may conduct intermediate analysis of gate 210 (FIG. 4) to determine whether gate work function (wƒg) 230 (FIG. 4) meets the desired work function threshold. The analysis performed by work function equivalence determinator 368 may involve determining an elapsing of a pre-determined implantation time while ions 240, 244 (FIG. 4) are being implanted using the desired dose and energy values determined above. Alternatively, work function equivalence determinator 368 may use a sensor on ion implanter system 10, 110 to determine whether the correct dose has been implanted by determining whether a specific dosage of ions 240, 244 has been transmitted, by directly monitoring metal gate 210 or by any other means now known or later developed.

It should be recognized that while a particular compartmentalization of functional components of work function adjusting system has been shown, it is envisioned that the arrangement may be altered within the scope of the invention.

Operation Methodology

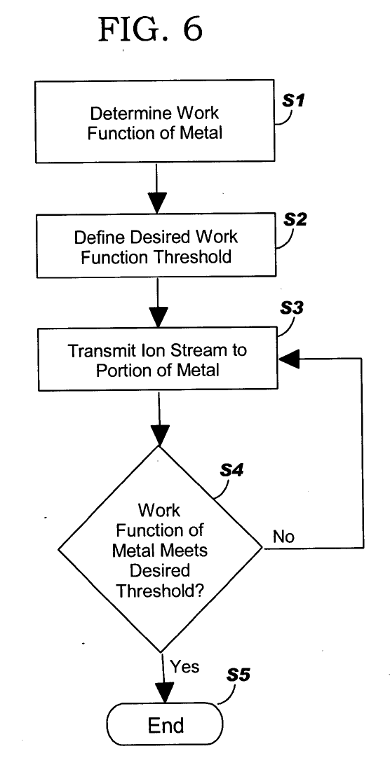

Referring to FIG. 6, a flow diagram of operation methodology for adjusting metal work function by ion implanter system 10, 110 (FIGS. 2-3) in target 6, 148 (FIG. 4) will now be described. Referring to FIG. 6 in conjunction with FIGS. 2-5, in a first step S1, work function determinator 356 determines gate work function (wƒg) 230 of metal gate 210. Determination step S1 may include direct testing of a material that comprises metal gate 210 using a machine that measures work function of a material, such as by using a laser, ultraviolet photoemission, or any other method now known or later determined. These machines are well known in the art and, as such, will not be described in detail herein. In the alternative, determination step S1 may determine gate work function (wƒg) of an unknown material by comparing it to that of a known material, as is well known in the art. Alternatively, determination step S1 may include retrieval from storage in Db 348 or other memory of system controller 20, 150 and/or input as a parameter input 380 to system controller 20, 150 of a previously determined gate work function (wƒg) or any other method now known or later developed in the art for determining a work function.

In step S2, desired work function determinator 360 determines a desired work function threshold to which gate work function (wƒg) 230 will be adjusted. The desired work function threshold may be a range and is preferably substantially equivalent to substrate work function (wƒs) 234 but may also be any other work function that the user desires. As such, in one embodiment determination step S2 may include determination of substrate work function (wƒs) using any of the methods described above for determining gate work function (wƒg). In the alternative, the desired work function threshold may be set to any work function that the user desires.

In step S3, at least one ion 240, 244 is transmitted to at least a portion of gate 210 of target 6, 148. Transmission step S3 may be accomplished using ion implanter system 10, 110 as controlled by system controller 20, 150 or by any other system and/or controller now known or later developed for implanting ions. The implanted dose of ions 240, 244 may be a high dose, wherein high dose is defined as being on the order of about 1E116 cm⁻². In any event, at least one ion 240, 244 strikes gate 210 of target 6, 148, causing ion 244 to be implanted within the structure of gate 210. This new addition of ion 244 to the structure of gate 210 causes gate work function (wƒg) 230 to change. As indicated above, ion 240, 244 may be comprised of any positively or negatively charged atoms, which are now known or later discovered to change the work function of a metal gate of the type described herein. Some examples include, but are not limited to Hydrogen, Helium, Boron, Carbon, Nitrogen, Oxygen, Fluorine, Neon, Argon, Krypton, Xenon, Phosphorus, Arsenic or ions of any of the previously referenced gate metals. Ion implanter system 10, 110 (FIGS. 2-3) may continue to generate ion 240 for implantation within gate 210 of target 6, 148 until gate work function (wƒg) 230 meets a predetermined desired work function threshold.

In step S4, the work function equivalence determinator 368 determines whether gate work function (wƒg) 230 meets the desired work function threshold. This desired work function threshold may be, for example, a predetermined work function value or a range. In any event, the work function threshold is sufficient to result in a work function that is preferably substantially equivalent to substrate work function (wƒs) 234. As indicated above, the determination may be made using previously gathered empirical data, by using an equation having such variables as the dose and energy of ions being implanted and the length of time during which ions are implanted or by any other method now known or later developed in the art. If the determination is made in step S4 that gate work function (wƒg) 230 meets the desired work function threshold, the process ends. Otherwise, steps S3-S4 are repeated until gate work function (wƒg) 230 meets the desired work function threshold.

### CONCLUSION

In the previous discussion, it will be understood that the method steps discussed are performed by a processor, such as PU 342 of system controller 20, 150, executing instructions of program product 350 stored in memory. It is understood that the various devices, modules, mechanisms and systems described herein may be realized in hardware, software, or a combination of hardware and software, and may be compartmentalized other than as shown. They may be implemented by any type of computer system or other apparatus adapted for carrying out the methods described herein. A typical combination of hardware and software could be a general-purpose computer system with a computer program that, when loaded and executed, controls the computer system such that it carries out the methods described herein. Alternatively, a specific use computer, containing specialized hardware for carrying out one or more of the functional tasks of the invention could be utilized. The present invention can also be embedded in a computer program product, which comprises all the features enabling the implementation of the methods and functions described herein, and which—when loaded in a computer system—is able to carry out these methods and functions. Computer program, software program, program, program product, or software, in the present context mean any expression, in any language, code or notation, of a set of instructions intended to cause a system having an information processing capability to perform a particular function either directly or after the following: (a) conversion to another language, code or notation; and/or (b) reproduction in a different material form.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. A method of adjusting a work function of a metal in a target, the method comprising the steps of:
determining the work function of the metal;
determining a desired work function threshold; and
implanting at least a portion of the metal with ions until the work function of the metal meets the desired work function threshold.

2. The method of claim 1, wherein the desired work function threshold is a range.

3. The method of claim 2, wherein the target includes a substrate, and wherein a work function of the substrate is within the range.

4. The method of claim 1, wherein the implanting step utilizes an ion beam.

5. The method of claim 1, wherein the implanting step utilizes ions accelerated from a plasma.

6. The method of claim 1, wherein the target is a semiconductor device.

7. The method of claim 1, wherein the ions comprise at least one ion selected from the group consisting of gold, silver, aluminum, copper, chromium, nickel, carbon, germanium, cobalt, silicon, platinum, titanium, hydrogen, helium, boron, carbon, nitrogen, oxygen, fluorine, neon, argon, krypton, xenon, phosphorus and arsenic.

8. The method of claim 1, wherein the metal comprises a material selected from the group consisting of gold, silver, aluminum, copper, chromium, nickel, carbon, germanium, cobalt, silicon, platinum and titanium.

9. The method of claim 1, wherein the metal comprises titanium nitride.

10. The method of claim 9, wherein the ions comprise at least one ion selected from the group consisting of titanium and nitrogen.

11. The method of claim 1, wherein the metal comprises a metal selected from the group consisting of rhenium, niobium, tungsten, tantalum and molybdenum.

12. The method of claim 1, wherein the target includes a substrate, and wherein the substrate comprises a material selected from the group consisting of germanium, silicon and gallium arsenide.

13. A system for adjusting a work function of a metal in a target, the system comprising:
means for determining the work function of the metal;
means for determining a desired work function threshold; and
means for implanting at least a portion of the metal with ions until the work function of the metal meets the desired work function threshold.

14. The system of claim 13, wherein the desired work function threshold is a range.

15. The system of claim 14, wherein the target includes a substrate, and wherein a work function of the substrate is within the range.

16. The system of claim 13, wherein the means for implanting utilizes an ion beam.

17. The system of claim 13, wherein the means for implanting utilizes ions accelerated from a plasma.

18. The system of claim 13, wherein the target is a semiconductor device.

19. The system of claim 13, wherein the ions comprise at least one ion selected from the group consisting of gold, silver, aluminum, copper, chromium, nickel, carbon, germanium, cobalt, silicon, platinum, titanium, hydrogen, helium, boron, carbon, nitrogen, oxygen, fluorine, neon, argon, krypton, xenon, phosphorus and arsenic.

20. The system of claim 13, wherein the metal comprises a material selected from the group consisting of gold, silver, aluminum, copper, chromium, nickel, carbon, germanium, cobalt, silicon, platinum and titanium.

21. The system of claim 13, wherein the metal comprises titanium nitride.

22. The system of claim 21, wherein the ions comprise at least one ion selected from the group consisting of titanium and nitrogen.

23. The system of claim 13, wherein the metal comprises a material selected from the group consisting of rhenium, niobium, tungsten, tantalum and molybdenum.

24. The system of claim 13, wherein the target includes a substrate, and wherein the substrate includes a material selected from the group consisting of germanium, silicon and gallium arsenide.

25. A computer program product comprising a computer useable medium having computer readable program code embodied therein for controlling an ion implanter system that generates ions used in adjusting a work function of a metal in a target, the program product comprising:
program code configured to determine the work function of the metal;
program code configured to determine a desired work function threshold; and
program code configured to control the ion implanter system to implant ions into the metal until the work function meets the desired work function threshold.

26. The program product of claim 25, wherein the ion implanter system produces a high dose ion implant.

27. The program product of claim 25, wherein the target includes a substrate, and wherein the desired work function threshold is substantially equivalent to a work function of the substrate.
